(19) United States
(12) Patent Application Publication
(10) Pub. No.: US 2016/0073543 A1
(43) Pub. Date: Mar. 10, 2016

(54) ZONEABLE POWER REGULATION

(71) Applicant: HEWLETT-PACKARD DEVELOPMENT COMPANY, L.P., Houston, TX (US)

(72) Inventors: Peter Andrew VanNess, Houston, TX (US); Scott T Christensen, Houston, TX (US); Peter Hansen, Cypress, TX (US); Victoria Jeanine Doehring, Houston, TX (US)

(21) Appl. No.: 14/782,323

(22) PCT Filed: Apr. 3, 2013
(86) PCT No.: PCT/US2013/035147

§ 371 Date: Oct. 3, 2015

(51) Int. Cl. H05K 7/14

(52) U.S. Cl. CPC H05K 7/1489; H05K 7/1492

(57) ABSTRACT

A system and method for zoneable power regulation are provided herein. A system for zoneable power regulation may include a power supply, a blade system, and a controller. One or more blade servers consumes power from the power supply. The controller groups each of the one or more blade servers into one or more zones, and power is consumed by each zone according to a power capping strategy, the power capping strategy including power regulation using a device and by asserting a duty cycle.

### BACKGROUND

A data center is a facility used to house computer networks, computer systems and associated components, such as telecommunications and storage systems. It may include redundant or backup power supplies, redundant data communications connections, environmental controls (for example, air conditioning, fire suppression, etc.) and security devices. Data center design, construction, and operation may be in accordance with standard documents from accredited professional groups.

A data center can occupy one room of a building, one or more floors, or an entire building. The equipment in a data center may be in the form of servers mounted in rack cabinets. Each rack mounted server includes one or more power supplies. A data center may also include blade systems. A blade system includes one or more blade servers that are mounted in an enclosure that includes several slots, one slot for each blade server. In this manner, the enclosure, or chassis, can hold multiple blade servers that are mounted on a single board. The chassis may obtain power from one or more power supplies that are associated with the chassis as a whole.

### BRIEF DESCRIPTION OF THE DRAWINGS

Certain examples are described in the following detailed description and in reference to the drawings, in which:

FIG. 1A is a block diagram of a system;

FIG. 1B is a block diagram of another system;

FIG. 2 is a process flow diagram of a method for zoneable power regulation;

FIG. 3 is a block diagram showing tangible, non-transitory, computer readable media that regulates power.

### DETAILED DESCRIPTION OF SPECIFIC EXAMPLES

As discussed above, one or more blade servers may be contained in the chassis of a blade system. Power, cooling, networking, and access to peripheral devices are typically provided to the blade servers through the chassis. The chassis may also house power supplies, cooling devices, electrical power connections, data interconnections, and peripheral 110 devices that communicate with the blade servers. During operation, each blade server consumes power from the one or more power supplies to the chassis.

Power consumption within a data center may be managed following various strategies. The limits on power consumption within a data center may be referred to as power capping. Typically, power capping strategies concentrate on power usage at the chassis level for rack mount servers, blade servers, and both one- and multi-node chassis blade systems. A cap refers to a type of limit, such that a power cap is a limit on power and a power consumption cap is a limit on power consumption. A node refers to a group of one or more blade servers within a blade system. In some examples, each node is a cartridge within the chassis. Group capping may be performed, however, group capping applies to rack and chassis level granularity, not blade server level granularity.

Examples described herein relate generally to techniques for zoneable power regulation within a chassis enclosure. More specifically, systems and methods described herein relate to regulating power consumption at various levels of granularity within a chassis enclosure. Furthermore, each blade server may be grouped into a node or a zone, and the chassis power may be regulated on a per-blade level, per-node level, or a per-zone level. As a result, a power cap may be set for each blade server, node, or zone within the blade system.

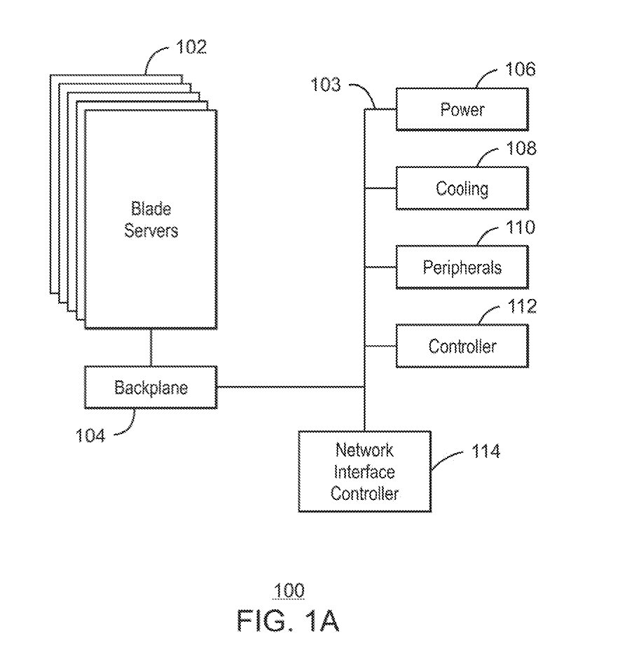

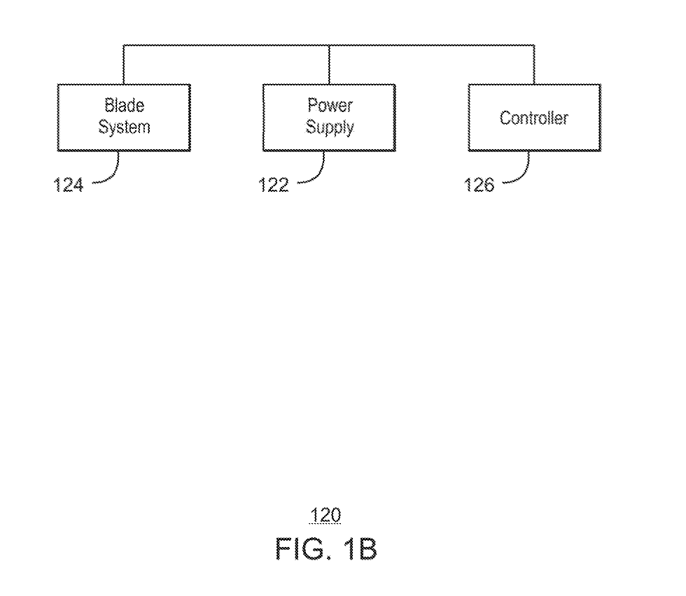

FIG. 1A is a block diagram of a system 100. The system 100 may be a blade system. In some examples, the blade system is included within a chassis. Moreover, in some examples, the blade system is a multi-tenant system, and the blade servers of each tenant are grouped according to power consumption. The system 100 includes a plurality of blade servers 102. In examples, the blade servers 102 may also be referred to as a blade system. Each blade server 102 may include one or more processors, memory, storage, and network interfaces. For example, each blade server 102 may include a processor that is adapted to execute stored instructions. The processor can be a single core processor, a multi-core processor, a computing cluster, or any number of other configurations. Each blade server 102 may connect to a chassis backplane 104 through a bus 103. The bus 103 may be a series of interconnects. The chassis backplane 104 provides each blade server 102 with access to resources coupled to the chassis through the bus 103.

In particular, the system may include a power subsystem 106 that supplies power to the system 100. The power system 106 may be used to supply power to each of the blade servers 102. In some examples, the power system 106 is a single power supply. Additionally, in some examples, the power system 106 is a redundant set of power supplies, wherein one or more backup power supplies are used to ensure a continuous supply of power to the system 100. The system is also cooled by a cooling subsystem 108. The cooling subsystem 108 may include fans operated by one or more controllers. The cooling subsystem 108 may also be a liquid cooled system.

One or more peripherals 110 may be included in the system 100. The peripherals 110 include any component that can be used in conjunction with the blade servers 102. For example, the peripherals 110 include storage devices such as a hard drive, storage area network (SAN), and input/output (I/O) devices. In some examples, each blade server 102 may include an on-board memory device that stores instructions that are executable by the processor of each blade device. The on-board memory device can include random access memory (RAM), read only memory (ROM), flash memory, or any other suitable memory systems.

In some examples, an I/O device may include a keyboard and a pointing device, wherein the pointing device may include a touchpad or a touchscreen, among others. Additionally, the I/O device may be a touchscreen that includes a virtual keyboard that is rendered on the touchscreen. The I/O device may also be externally connected to the system 100, or the I/O device may be internal to the system 100. The peripherals 110 may also include a display adapted to render the output of the system 100. In examples, the display may be a display screen that is external to the system 100. Additionally, in examples, the display and an I/O device may be combined into one touchscreen.

The system 100 also includes a controller 112 that is used to control each blade server 102. In some examples, the chassis of the blade system is used to route each blade server to the controller 112 via a series of interconnects. Additionally, in some examples, each node is routed to the controller 112. In such a scenario, when there are multiple blade servers for each node, there is only one signal routed to the controller 112 from the node. The node may serve as the cartridge, with each blade server enabling processor, networking, and memory functionality. In this manner, throttling may be on a node level in a multi-blade server per node. However, in some examples, a single blade server 102 can initiate a request to throttle for the entire node. The controller 112 may also be used to manage each blade server 102, and may include management device logic. The controller 112 may also be a complex programmable logic device (CPLD) or a microcontroller. In some examples, the management device logic allocates one or more nodes to one or more capping zones. A capping zone is a set of nodes that are subject to the same power cap. The controller 112 may also be used to cap the power consumption of each blade server individually. Further, the controller 112 may cap the power consumption within a blade system chassis using a per-node basis or a per-zone basis. As a result, using zoneable power regulation can modify the power capping strategy down to a single blade server granularity. The power capping strategy may be a dynamic technique to regulate power consumption that is implemented using system hardware and firmware. In this manner, a power capping strategy is not dependent on an operating system or applications. In some examples, a user may modify the power capping strategy. Further, in some examples, the power capping strategy may be automatically modified based on rules for inter-zone power regulation or intra-zone power regulation. Although the description of the present techniques described herein use a zone basis or a node basis for power capping, the present techniques may also be used on a blade server basis for power capping.

The controller 112 may implement a set of rules to enable inter-zone power regulation. Rules for inter-zone power regulation may cap power across zones based on the relationship between the various zones. The controller 112 may also implement a set of rules to enable intra-zone power regulation, where the power consumption of elements within each zone is individually capped. Elements within each zone include one or more nodes, with each node including one or more blade servers. The controller 112 may also implement a power capping strategy.

In some examples, each blade server 102 is routed to the controller 112 using a series of interconnects. The controller 112 is able to dynamically assign each blade server 102 to a node. In some examples, in response to a request, the controller 112 may provide feedback including an identification of nodes allocated in the system 100 and an indication of which nodes belong to which zones. The feedback may also include the designation of which blade servers belong to which node. The allocation of the nodes and blade servers may be modified by a user. In some examples, the ability to modify a zone may be implemented through a licensing structure. In particular, a user may modify the zone allocation after the user has obtained a license with permission to modify the zone allocation.

The system 100 also includes a network interface controller (NIC) 114. In some examples, the NIC 114 may be one or more NICs integrated into each blade server 102. Additionally, in some examples, the NIC 114 is integrated into the backplane 104. The NIC 114 may be used to connect the system 100 to networks such as the Internet. In examples, the NIC 114 may implement a telnet protocol, transmission control protocol (TCP), internet protocol (IP), or any other networking communication protocol.

FIG. 1B is a block diagram of another system 120. A power supply 122 may be used to supply power to each of the blade servers 102. In some examples, the power supply is a component of the power system 106 as illustrated in FIG. 1A. The system 120 also includes a blade system 124. The blade system 124 may include a one or more blade servers 102 as illustrated in FIG. 1A.

The system 120 also includes a controller 126 that is used to control the blade system 124 and the power supply 122. In some examples, the controller 126 is the controller 112 as illustrated in FIG. 1A. The controller may group one or more blade servers of the blade system 124 into one or more zones. Power is consumed by each zone according to a power capping strategy implemented by the controller. The power capping strategy may include power regulation using a device and by asserting a duty cycle. The device may be using a general purpose input/output device, a networking device, a power control device, or any combinations thereof. Each device may be used to modify the power output from the power supply, such that the power to each node, blade, or zone is regulated. Additionally, the duty cycle asserted by the controller 126 may be asserted using any modulation technique, such as pulse width modulation or pulse duration modulation.

It is to be understood that the block diagrams of FIGS. 1A and 1B are not intended to indicate that the system 100 and the system 120 are to include all of the components shown in FIG. 1A and FIG. 1B, respectively. Further, the system 100 and the system 120 may include any number of additional components not shown in FIGS. 1A and 18, depending on the design details of a specific implementation.

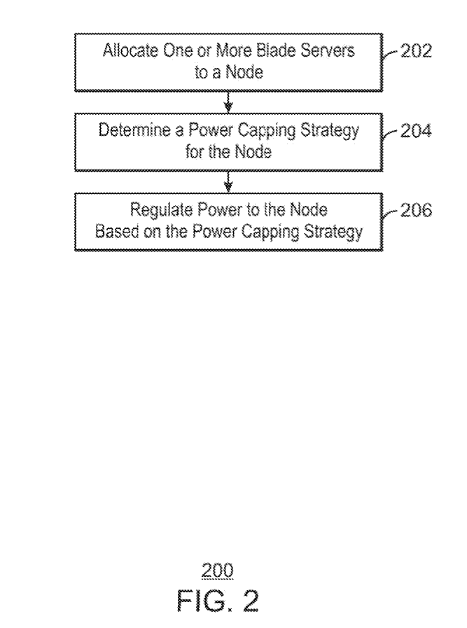

FIG. 2 is a process flow diagram of a method 200 for zoneable power regulation. At block 202, one or more blade servers may be allocated to a node. In some examples, each node of a plurality of nodes may be allocated to a capping zone, wherein each node includes at least one blade server. Each capping zone may group nodes based on similar power caps according to a power capping strategy. The one or more blade servers may be allocated to the node in response to a request from a controller, and the request may be derived from a set of rules. In examples, the rules may be used to determine a particular zone assignment for each blade server.

At block 204, a power capping strategy for each node of the plurality of nodes is determined. In examples, a power cap is determined. The power cap is a maximum power level that has been determined for each zone. In some examples, the power capping strategy may include a set of rules that may be applied to regulate the power to each node of the set of one or more nodes.

At block 206, the power to each node of the set of one or more nodes is regulated based on the power capping strategy. In some examples, the power to each node may be regulated using a duty cycle, where the duty cycle is asserted for each node in order to regulate the power consumed by each node based on the power cap. The duty cycle to a node may be removed or adjusted when that node's power consumption has fallen to less that the power cap for that node. Further, in some examples, the power to each node may be regulated using a general purpose input/output device. The power to each node may also be regulated using a networking device, power control device, and the like to modify the power output from a power system.

In some examples, the addition of power capping zones enables a user, such as a chassis manager, to use numerous inputs to provide capping with localized performance costs. Performance costs may be, for example, associated with the clock frequency of components within each zone, such as a central processing unit (CPU), a graphics processing unit (GPU), or a memory device. For example, a chassis manager can use inputs such as thermal data, anticipated power consumption, chassis configuration, and desired levels of service to cap the power consumed by each zone within a chassis. As a result, the chassis manager can enforce a power consumption cap of a power capping strategy using various techniques based on the sensor input data. These techniques include, but are not limited to, a round robin scheme to increase performance over the entire chassis, as well as developing a licensed environment where zones have weighted values attached to them for preferential treatment. In some examples, preferential treatment may include a variable power allocation for each zone, where zones with a higher value receive a higher preference when there is a contention for available power under the power capping scheme. The variable power allocation may depend on the type of license or service agreement purchased for the operation of the chassis.

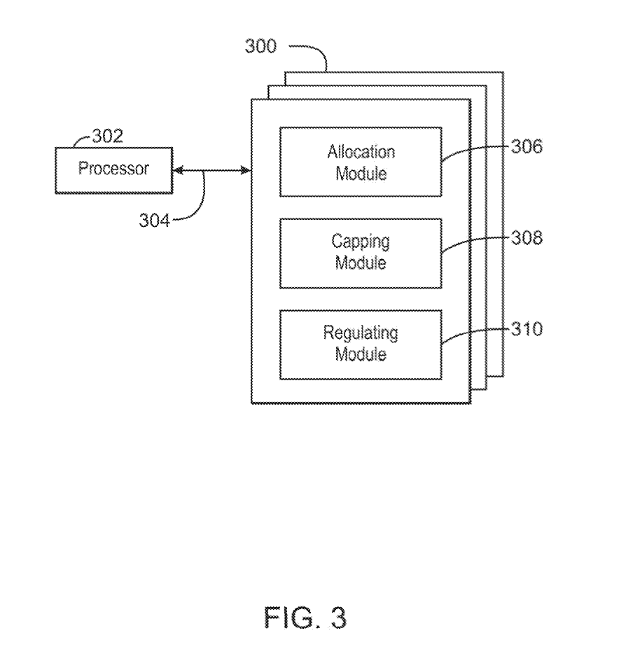

FIG. 3 is a block diagram showing tangible, non-transitory, computer-readable media 300 that regulates power. The computer-readable media 300 may be accessed by a processor 302 over a computer bus 304. Furthermore, the computer-readable media 300 may include code to direct the processor 302 to perform the steps of the current method.

The various software components discussed herein may be stored on the tangible, non-transitory, computer-readable media 300, as indicated in FIG. 3. For example, an allocation module 306 may be configured to direct the processor 302 to allocate one or more blade servers to one node of a plurality of nodes. In examples, each node of a plurality of nodes may be allocated to a capping zone, wherein each node includes at least one blade server. A capping module 308 may be configured to direct the processor 302 to determine a power capping strategy for each node of the plurality of nodes. In examples, a power cap is determined that is a maximum power level that has been determined for each zone. Further, a set of rules may be applied to regulate the power to each node of the set of one or more nodes based on the power cap. A regulating module 310 may be configured to direct the processor 302 to regulate the power to each node based on the power capping strategy.

It is to be understood that FIG. 3 is not intended to indicate that all of the software components discussed above are to be included within the tangible, non-transitory, computer-readable media 300 in every case. Further, any number of additional software components not shown in FIG. 3 may be included within the tangible, non-transitory, computer-readable media 300, depending on the specific implementation. For example, a licensing may be used to enable the modification of a capping zone according to a power capping strategy.

While the present techniques may be susceptible to various modifications and alternative forms, the exemplary examples discussed above have been shown only by way of example. It is to be understood that the technique is not intended to be limited to the particular examples disclosed herein. Indeed, the present techniques include all alternatives, modifications, and equivalents falling within the true spirit and scope of the appended claims.

What is claimed is:

1. A system for zoneable power regulation, comprising:
a power supply;
a blade system, wherein one or more blade servers consumes power from the power supply; and
a controller, wherein the controller groups each of the one or more blade servers into one or more zones, and power is consumed by each zone according to a power capping strategy, the power capping strategy including power regulation using a device and by asserting a duty cycle.

2. The system of claim 1, wherein a zone includes one blade server.

3. The system of claim 1, wherein the zones are modified in response to zone allocation by the controller.

4. The system of claim 1, wherein the zones are modified in response to zone allocation by a user.

5. The system of claim 1, wherein the controller provides feedback.

6. The system of claim 1, wherein the controller is a complex programming logic based (CPLD) device or a microcontroller.

7. The system of claim wherein a chassis of the blade system routes each blade server to the controller.

8. The system of claim 1, wherein the controller enables inter-zone power regulation.

9. The system of claim 1, wherein the controller enables intra-zone power regulation.

10. The system of claim 1, wherein the blade system is a multi-tenant system, and the blade servers of each tenant are grouped according to power controls.

11. A method for zoneable power regulation, comprising:
allocating one or more blade servers to each node of a plurality of nodes;
determining a power capping strategy for each node of the plurality of nodes; and
regulating the power to each node based on the power capping strategy, wherein a power consumption cap of the power capping strategy is enforced.

12. The method of claim 10, wherein the one or more blade servers are allocated to the node in response to a request from a controller that is derived from a set of rules.

13. The method of claim wherein each node of the plurality of nodes is assigned to a capping zone.

14. The method of claim 10, further comprising regulating the power consumed by each node based on the power cap by asserting a duty cycle, using a general purpose input/output device, using a networking device, using a power control device, or any combinations thereof.

15. A tangible, non-transitory, computer-readable medium comprising code to direct a processor to:
allocate one or more blade servers to each node of a plurality of nodes;
determine a power capping strategy for each node of the plurality of nodes; and
regulate the power to each ode based on the power capping strategy.
